(19) United States
(12) Patent Application Publication
(10) Pub. No.: US 2024/0175128 A1
(43) Pub. Date: May 30, 2024

(54) MIST CVD FILM FORMATION DEVICE AND FILM FORMATION METHOD

(71) Applicant: Murata Manufacturing Co., Ltd., Nagaokakyo-shi (JP)

(72) Inventors: Hiroshi SHIRAKI, Nagaokakyo-shi (JP); Daisuke KAN, Uji-shi (JP); Yuichi SHIMAKAWA, Uji-shi (JP)

(21) Appl. No.: 18/432,699

(22) Filed: Feb. 5, 2024

Related U.S. Application Data
(63) Continuation of application No. PCT/JP22/40984, filed on Nov. 2, 2022.

(30) Foreign Application Priority Data
Feb. 4, 2022 (JP) 2022-016412

(51) Int. Cl. C23C 16/448; C23C 16/458; C23C 16/46

(52) U.S. Cl. CPC C23C 16/4486; C23C 16/458; C23C 16/46

(57) ABSTRACT

A mist CVD film formation device that includes: a film forming chamber including: a mist inflow port through which a film forming mist containing a mist of a film forming raw material and a carrier gas flows into the film forming chamber, a stage that supports a film forming target, and a mist outflow port through which the film forming mist flows out of the film forming chamber, wherein an outflow port sectional area is smaller than a film forming chamber interior sectional area; and a heater that heats the stage.

### CROSS REFERENCE TO RELATED APPLICATIONS

The present application is a continuation of International application No. PCT/JP2022/040984, filed Nov. 2, 2022, which claims priority to Japanese Patent Application No. 2022-016412, filed Feb. 4, 2022, the entire contents of each of which are incorporated herein by reference.

### TECHNICAL FIELD

The present invention relates to a mist CVD film formation device and a film formation method.

### BACKGROUND ART

As a method of forming a film on a substrate, a mist CVD method is known. The mist CVD method has characteristics such as (1) being capable of film formation in the atmosphere (non-vacuum process), (2) being capable of film formation on a three-dimensional object, (3) being capable of expecting reduction of the cost, (4) being capable of film thickness control at a nano level, and (5) being capable of film formation of a high-quality thin film at a level that can be used in a transistor, and is expected to be applied in various ways such as preparation of a power semiconductor material using α-Ga₂O₃.

Patent Document 1 describes a mist CVD film formation device of a type using a tubular furnace. This type is called a hot-wall-type mist CVD film formation device, and has features that the device configuration is simple and heating up to high temperature is possible.

Patent Document 2 describes a fine channel type mist CVD film formation device having a small height in a film forming chamber in which a distance between a surface of a substrate and an inner wall of a film forming chamber is set to a distance in a range of 0.1 mm to 10.0 mm.
Patent Document 1: Japanese Patent Application Laid-Open No. 2016-72526
Patent Document 2: Japanese Patent Application Laid-Open No. 2005-307238

### SUMMARY OF THE INVENTION

In the hot-wall-type mist CVD film formation device disclosed in Patent Document 1, a heater is disposed outside a cylindrical quartz tube to heat a substrate. However, this type of mist CVD film formation device has a problem that distributions of the temperature and the flow rate in the film forming chamber when the mist is caused to flow increase, and it is difficult to stably produce a target film. In addition, since one continuous quartz tube is used in the tubular furnace, it is difficult to make the material around the substrate and the material from a mist inflow port to the substrate different from each other.

In the fine channel type mist CVD film formation device disclosed in Patent Document 2, it is said that the distributions of the temperature and the flow rate in the film forming chamber are uniform unlike the hot-wall-type mist CVD film formation device. On the other hand, the flow rate increases as the height of the film forming chamber decreases. As a result, there is a problem that the substrate temperature decreases and crystallinity of the film to be produced decreases.

The present invention has been made to solve the above problems, and an object thereof is to provide a mist CVD film formation device capable of obtaining a high-quality film and a film formation method using the mist CVD film formation device.

One aspect of the mist CVD film formation device of the present invention includes: a film forming chamber including: a mist inflow port through which a film forming mist containing a mist of a film forming raw material and a carrier gas flows into the film forming chamber, a stage that supports a film forming target, and a mist outflow port through which the film forming mist flows out of the film forming chamber, wherein an outflow port sectional area is smaller than a film forming chamber interior sectional area, the film forming chamber interior sectional area is a sectional area of a space in the film forming chamber in a cut surface obtained by cutting in a section orthogonal to a flowing direction of the film forming mist on the stage, and the outflow port sectional area is a sectional area of a space of the mist outflow port in a cut surface obtained by cutting the mist outflow port in the section orthogonal to the flowing direction of the film forming mist; and a heater that heats the stage.

Another aspect of a mist CVD film formation device of the present invention includes: a film forming chamber including: a mist inflow port through which a film forming mist containing a mist of a film forming raw material and a carrier gas flows into the film forming chamber, a stage that supports a film forming target, and a mist outflow port through which the film forming mist flows out of the film forming chamber, wherein a thermal conductivity of a first member located close to the mist inflow port relative to the stage in the film forming chamber is lower than a thermal conductivity of a material of the stage; and a heater that heats the stage.

Still another aspect of a mist CVD film formation device of the present invention includes: a film forming chamber including: a mist inflow port through which a film forming mist containing a mist of a film forming raw material and a carrier gas flows into the film forming chamber, a stage that supports a film forming target, and a mist outflow port through which the film forming mist flows out of the film forming chamber, wherein a thermal conductivity of a member located on a top surface of the film forming chamber is lower than a thermal conductivity of a material of the stage; and a heater that heats the stage.

In the film formation method of the present invention, a film forming mist containing a mist of a film forming raw material and a carrier gas is caused to flow into a film forming chamber of the mist CVD film formation device of the present invention, and film formation by a mist CVD method is performed on a film forming target placed on a stage.

According to the present invention, it is possible to provide a mist CVD film formation device and a film formation method capable of obtaining a high-quality film.

### BRIEF EXPLANATION OF THE DRAWINGS

FIG. 1 is a device diagram schematically showing a configuration including a mist CVD film formation device, a mist introduction pipe and a mist discharge pipe, and members therearound.

FIG. 2 is an enlarged sectional view of a mist CVD film formation device.

FIG. 3 is a top view of a mist CVD film formation device.

FIG. 4 is a schematic view showing a change in mist particles when a film forming mist is heated.

FIG. 5 is a sectional view taken along line A-A in FIGS. 2 and 3.

FIG. 6 is a sectional view taken along line B-B in FIGS. 2 and 3.

FIG. 7 is a sectional view schematically showing a mist CVD film formation device not including a mist flow restricting member.

FIG. 8 is an enlarged sectional view schematically showing an example of a mist CVD film formation device in which a material of a slope is the same as a material of a stage.

FIG. 9 is an enlarged sectional view schematically showing an example of a mist CVD film formation device including a top plate having low thermal conductivity.

FIG. 10 is a graph showing XRD (X-ray diffraction) patterns of thin films produced in Example 1 and Comparative Example 1.

FIG. 11 is a graph showing the XRD pattern of a sample prepared by changing a height of a space in a film forming chamber within a range of 0.5 mm, 0.7 mm, 1.0 mm, and 5.0 mm when the mist flow restricting member is not used.

### DETAILED DESCRIPTION OF THE INVENTION

Hereinafter, a mist CVD film formation device of the present invention will be described.

However, the present invention is not to be considered limited to the following configurations, and can be appropriately modified and then applied without changing the scope of the present invention. The present invention also includes a combination of two or more of individual desirable configurations of the present invention described below.

One aspect of the mist CVD film formation device of the present invention includes: a film forming chamber including: a mist inflow port through which a film forming mist containing a mist of a film forming raw material and a carrier gas flows into the film forming chamber, a stage that supports a film forming target, and a mist outflow port through which the film forming mist flows out of the film forming chamber, wherein an outflow port sectional area is smaller than a film forming chamber interior sectional area, the film forming chamber interior sectional area is a sectional area of a space in the film forming chamber in a cut surface obtained by cutting in a section orthogonal to a flowing direction of the film forming mist on the stage, and the outflow port sectional area is a sectional area of a space of the mist outflow port in a cut surface obtained by cutting the mist outflow port in the section orthogonal to the flowing direction of the film forming mist; and a heater that heats the stage.

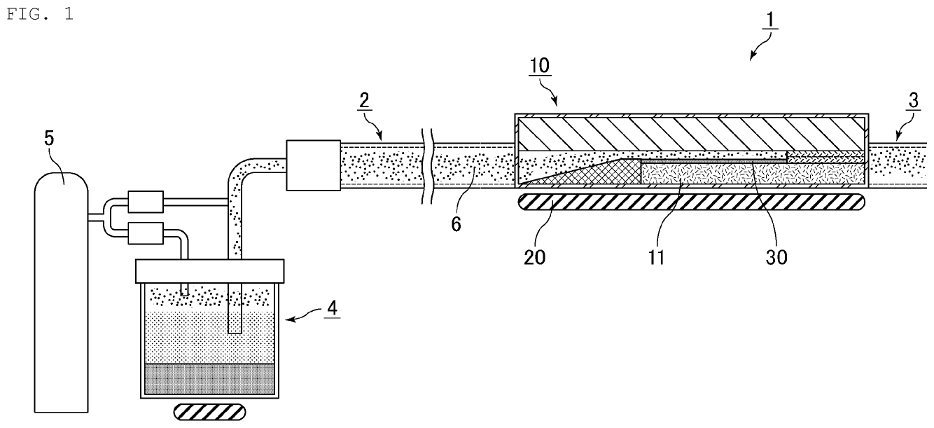

FIG. 1 is a device diagram schematically showing a configuration including the mist CVD film formation device, a mist introduction pipe and a mist discharge pipe, and members therearound.

A mist CVD film formation device 1 shown in FIG. 1 includes a film forming chamber 10 and a heater 20. The mist introduction pipe 2 and the mist discharge pipe 3 are connected to the film forming chamber 10.

A gas supply unit 4 and a mist generator 5 are arranged upstream of the mist introduction pipe 2. In the mist generator 5, a solution of a metal compound or the like as a film forming raw material is atomized by an ultrasonic transducer or the like to generate a mist of the film forming raw material. A carrier gas is supplied from the gas supply unit 4. The mist of the film forming raw material and the carrier gas are mixed to form a film forming mist 6, and the film forming mist 6 is introduced from the mist introduction pipe 2 into the mist CVD film formation device 1.

The film forming chamber 10 is provided with a stage 11, and the stage 11 is heated by a heater 20. A film forming target 30 is placed on the stage 11 and heated. When the film forming mist 6 comes into contact with the film forming target 30 on the stage 11, a thermal reaction occurs, and a film of the compound contained in the film forming mist 6 is formed on the surface of the film forming target 30.

The film forming mist 6 is discharged from the mist discharge pipe 3 after being subjected to film formation of the film forming target 30 in the mist CVD film formation device 1.

The film forming target to be subjected to film formation in the CVD film formation device is not particularly limited, and examples thereof include a flat plate-like object such as a substrate or a film, an object having a three-dimensional structure such as a sphere, a cone, a column, or a ring, or a powder.

The substrate as the film forming target may be any of an insulator substrate, a conductive substrate, a semiconductor substrate, and a resin substrate. The substrate may be a single crystal substrate or a polycrystalline substrate.

For example, in addition to glass substrates, and oxides such as quartz, gallium oxide, indium oxide, vanadium oxide, rhodium oxide, alumina, sapphire, barium titanate, cobalt oxide, chromium oxide, copper oxide, dysprosium scandiate, diiron trioxide, triiron tetraoxide, gadolinium scandiate, lithium tantalate, potassium tantalate, lanthanum aluminate, lanthanum strontium aluminate, lanthanum strontium gallate, lanthanum strontium aluminum tantalate, magnesium oxide, spinel, manganese oxide, nickel oxide, quartz, scandium magnesium aluminate, strontium oxide, strontium titanate, tin oxide, tellurium oxide, titanium oxide, YAG, yttria-stabilized zirconia, yttrium aluminate, and zinc oxide, metals such as silicon, germanium, silicon carbide, graphite, mica, calcium fluoride, silver, aluminum, gold, copper, iron, nickel, titanium, tungsten, and zinc may be selected, and the substrate is not limited thereto. Strontium titanate (STO) can be preferably used.

When the substrate is a resin substrate, examples thereof include polyethylene terephthalate (PET), polyethylene (PE), polypropylene (PP), polyvinyl chloride (PVC), polyimide (PI), polyamideimide (PAI), polyvinylidene fluoride (PVDF), polycarbonate (PC), and a liquid crystal polymer (LCP).

The thickness and size (area) of the film forming target are not particularly limited.

The mist generated by the mist generator is preferably obtained by atomizing a solution in which a metal salt or a metal complex is dispersed or dissolved in a liquid.

Examples of the metal salt include a metal chloride, a metal bromide, a metal iodide, a hydroxide, an acetate, a carbonate, a sulfate, and a nitrate.

Examples of the metal complex include an acetylacetonate complex, a carbonyl complex, an ammine complex, and a hydride complex.

Specific examples thereof include zinc acetate, zinc (II) acetylacetonate, chromium (III) acetylacetonate, copper (II) acetylacetonate, nickel (II) acetylacetonate, palladium (II) acetylacetonate, iron (III) acetylacetonate, indium (III) acetylacetonate, gallium (III) acetylacetonate, and tin (II) chloride.

Examples of the liquid constituting the mist include water and an organic solvent. The organic solvent is preferably an alcohol. The liquid may be a mixture of water and an organic solvent, or a mixed solvent of water and an alcohol (methanol).

The concentration of the raw material (metal salt or metal complex) in the mist is preferably 0.1 mmol/L to 1000 mmol/L (1 mol/L), and more preferably 0.1 mmol/L to 100 mmol/L.

In the mist generator, a mist is generated using an ultrasonic (for example, 2.4 MHZ) transducer.

The carrier gas is not particularly limited, and examples thereof include N₂ gas, argon gas, O₂ gas, and O₃ gas). The carrier gas may be a gas obtained by adding O₂ gas, O₃ gas), or the like at a low concentration to an inert gas such as N₂ gas or argon gas.

The flow rate of the carrier gas is not particularly limited, and is preferably 0.1 L/min to 10 L/min, and more preferably 1 L/min to 5 L/min.

The flow rate of the carrier gas is not particularly limited, and is preferably 0.1 m/s to 100 m/s, and more preferably 1 m/s to 20 m/s in the film forming chamber.

At the time of film formation, the stage is heated by a heater. The temperature of the heater is preferably set so that the temperature on the stage is equal to or higher than the boiling point of the solvent contained in the mist.

Since the heater is intended to heat the stage, it is preferable to provide the heater at a position close to the stage and immediately below the stage. The type of the heater is not particularly limited, and a planar heater, a mantle heater, or the like can be used. In addition, the entire film forming chamber may be heated, and a device in which a heater is provided to heat a stage by heating the entire film forming chamber is also included in the mist CVD film formation device of the present invention.

The thickness of the film formed in the mist CVD film formation device may be 1 nm or more, 10 nm or more, or 100 nm or more. The thickness may be 1000 nm or less, or 10,000 nm or less.

In addition, from the viewpoint of productivity, a film formation rate (film formation thickness per unit time) is preferably high, and the film formation rate is preferably 1 nm/min or more. However, when the film formation rate is too high, the quality of the film may be deteriorated, and thus the film formation rate is preferably 500 nm/min or less.

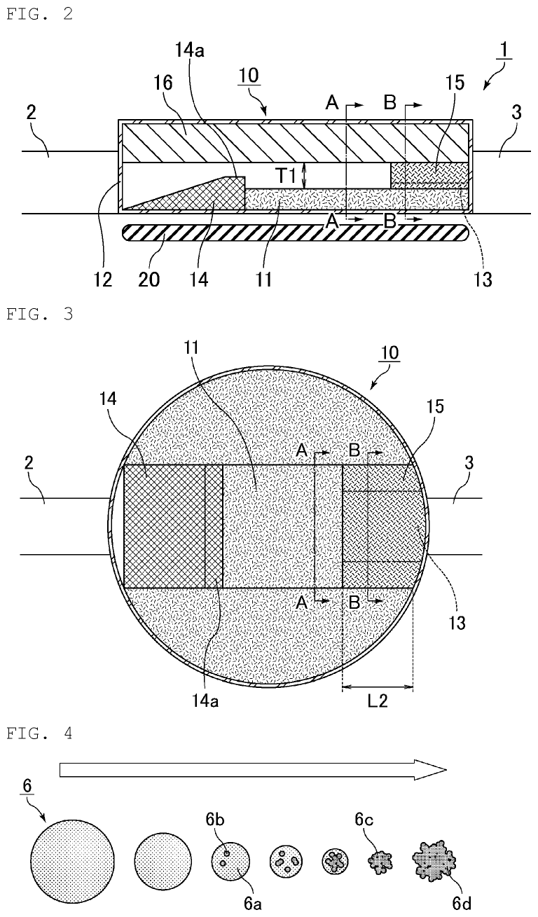

FIG. 2 is an enlarged sectional view of the mist CVD film formation device, and FIG. 3 is a top view of the mist CVD film formation device. FIG. 3 schematically shows an internal structure of the film forming chamber excluding a member located on a top surface of the film forming chamber. In the present specification, the film forming target is not shown in each of the drawings after FIG. 2.

The film forming chamber 10 shown in FIGS. 2 and 3 includes the stage 11 on which the film forming target is placed, a mist inflow port 12 which is an opening through which the film forming mist flows in, and a mist outflow port 13 which is an opening through which the film forming mist flows out.

In addition, the film forming chamber 10 includes a slope 14 on a side close to the mist inflow port 12 relative to the stage 11 (upstream side of the mist flow), and includes a mist flow restricting member 15 on the downstream side of the mist flow relative to the stage 11. The mist flow restricting member 15 is a member that narrows a mist flow path, and constitutes the mist outflow port 13. The length (length indicated by double-headed arrow L2 in FIG. 3) of the mist flow restricting member 15 along the flowing direction of the film forming mist is not particularly limited.

In addition, a top plate 16 is provided on a side opposite to the stage 11 in the thickness direction of the film forming chamber 10.

The height of the space in the film forming chamber 10 on the stage 11 is a height indicated by a double-headed arrow T1 in FIG. 2 and is a distance between the stage 11 and the top plate 16. The height is preferably 10 mm or less, and more preferably 2 mm or less.

When the height is 10 mm or less, the amount of the film forming mist flowing can be reduced. In addition, it is preferable because a high-quality film can be produced.

It is also preferable that a distance between the surface of the film forming target and the top plate 16 is 10 mm or less in a state where the film forming target is placed in the film forming chamber 10.

Although the film forming target may be placed on the stage as it is, in order to pattern the surface of the film forming target, a mask may be placed on the film forming target, and film formation may be performed. The mask is preferably a metal mask.

From this viewpoint, the height of the space in the film forming chamber 10 on the stage 11 may be 20 mm or less in consideration of the thickness of the film forming target and the total thickness of the film forming target and the mask.

Since it is preferable that a flat surface 14a of the slope 14 is set to be at the same height as the surface of the film forming target in a state where the film forming target is placed, it is also preferable that the distance between the flat surface 14a of the slope 14 and the top plate 16 is 10 mm or less.

A mist CVD film formation device in which a distance between the surface of the film forming target and the top plate is narrow (for example, 10 mm or less) is called a fine channel type mist CVD film formation device.

The stage 11 is heated by the heater 20. The heating increases the temperature in the film forming chamber 10. Thus, the liquid constituting the film forming mist in the film forming chamber 10 evaporates.

FIG. 4 is a schematic view showing a change in mist particles when the film forming mist is heated.

An arrow shown in an upper part of FIG. 4 indicates a direction in which the film forming mist 6 flows. The film forming mist is heated when flowing in the film forming chamber. The initial state is the first large mist from the left.

The evaporation of the liquid proceeds by the heating, and the size of the mist decreases as shown second from the left.

As the evaporation further proceeds, a component 6b (raw material component) dissolved in a liquid 6a constituting the mist precipitates as shown third, fourth, and fifth from the left, and the particles grow.

When the evaporation further proceeds and the liquid 6a almost evaporates, nanoparticles 6c containing the raw material component are formed as shown sixth from the left.

As the evaporation further proceeds, the nanoparticles 6c aggregate to form large particles 6d as shown seventh from the left.

In the mist CVD film formation device, a high-quality film can be obtained by bringing the mist particles into contact with the film forming target before the raw material component is precipitated. The mist CVD film formation device of the present invention is a device capable of obtaining a high-quality film by bringing the mist particles in which the raw material component does not precipitate into contact with the film forming target as shown first or second from the left in FIG. 4.

The mist CVD film formation device of the present invention is characterized in that when a film forming chamber interior sectional area which is a sectional area of a space in the film forming chamber in a cut surface obtained by cutting in a section orthogonal to the flowing direction of the film forming mist on the stage is compared with an outflow port sectional area which is a sectional area of a space of the mist outflow port in a cut surface obtained by cutting the mist outflow port in the section orthogonal to the flowing direction of the film forming mist, the outflow port sectional area is smaller than the film forming chamber interior sectional area. Since the mist CVD film formation device of the present invention is characterized as above, it becomes easy to bring the mist particles in which the raw material component does not precipitate into contact with the film forming target, and a high-quality film can be obtained.

Hereinafter, the characteristics will be described.

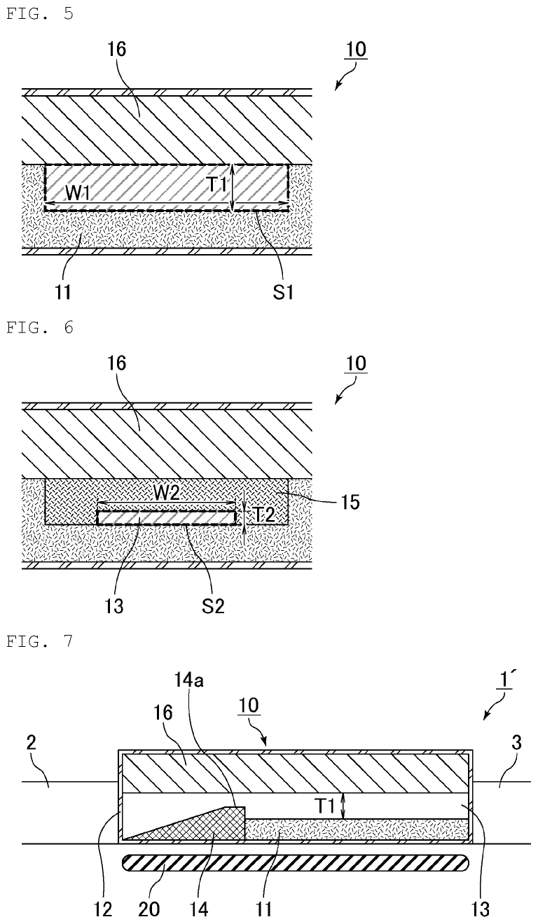

FIG. 5 is a sectional view taken along line A-A in FIGS. 2 and 3, and shows the cut surface obtained by cutting in the section orthogonal to the flowing direction of the film forming mist on the stage.

FIG. 6 is a sectional view taken along line B-B in FIGS. 2 and 3, and shows the cut surface obtained by cutting the mist outflow port along the section orthogonal to the flowing direction of the film forming mist.

In FIG. 5, a film forming chamber interior sectional area S1, which is the sectional area of the space in the film forming chamber, is indicated by a region surrounded by a broken line. The figure constituting the film forming chamber interior sectional area S1 is a rectangle having the stage 11 as a bottom side and the top plate 16 as an upper side.

In FIG. 6, the outflow port sectional area S2, which is the sectional area of the space in the mist outflow port, is indicated by a region surrounded by a broken line. The figure constituting the outflow port sectional area S2 is a rectangle having an inner wall surface of the mist flow restricting member 15 as the upper side and the left and right sides, and having the surface at the same height as the stage as the bottom side.

As can be seen from comparison between FIGS. 5 and 6, the outflow port sectional area S2 is smaller than the film forming chamber interior sectional area S1.

Since the outflow port sectional area is small, that is, the outflow port of the film forming mist is narrow, an internal pressure in the film forming chamber increases. As a result, evaporation of the liquid constituting the mist is less likely to proceed, and there is a high possibility that the liquid comes into contact with the film forming target in a mist state in which the raw material component does not precipitate. Thus, a high-quality film can be formed.

In FIG. 6, in order to reduce the outflow port sectional area S2, the height of the space of the mist outflow port (indicated by double-headed arrow T2 in FIG. 6) is made smaller than the height of the space in the film forming chamber on the stage (indicated by double-headed arrow T1 in FIG. 5). The width of the space of the mist outflow port (indicated by double-headed arrow W2 in FIG. 6) is made smaller than the width of the space in the film forming chamber on the stage (indicated by double-headed arrow W1 in FIG. 5).

The shape of the mist flow restricting member 15 is determined to reduce the outflow port sectional area S2.

FIG. 6 shows an example in which the height of the rectangle constituting the outflow port sectional area S2 is smaller than the height of the rectangle constituting the film forming chamber interior sectional area S1, and the width of the rectangle constituting the outflow port sectional area S2 is smaller than the width of the rectangle constituting the film forming chamber interior sectional area S1.

However, by changing the shape of the mist flow restricting member 15, the height of the rectangle constituting the outflow port sectional area S2 may be made smaller than the height of the rectangle constituting the film forming chamber interior sectional area S1, and the width of the rectangle constituting the outflow port sectional area S2 may be the same as the width of the rectangle constituting the film forming chamber interior sectional area S1, so that the outflow port sectional area S2 may be made smaller than the film forming chamber interior sectional area S1.

Furthermore, by changing the shape of the mist flow restricting member 15, the height of the rectangle constituting the outflow port sectional area S2 may be the same as the height of the rectangle constituting the film forming chamber interior sectional area S1, and the width of the rectangle constituting the outflow port sectional area S2 may be made smaller than the width of the rectangle constituting the film forming chamber interior sectional area S1, so that the outflow port sectional area S2 may be made smaller than the film forming chamber interior sectional area S1.

A ratio (S2/S1) of the outflow port sectional area S2 to the film forming chamber interior sectional area S1 is preferably 0.01 to 0.99, and more preferably 0.1 to 0.5.

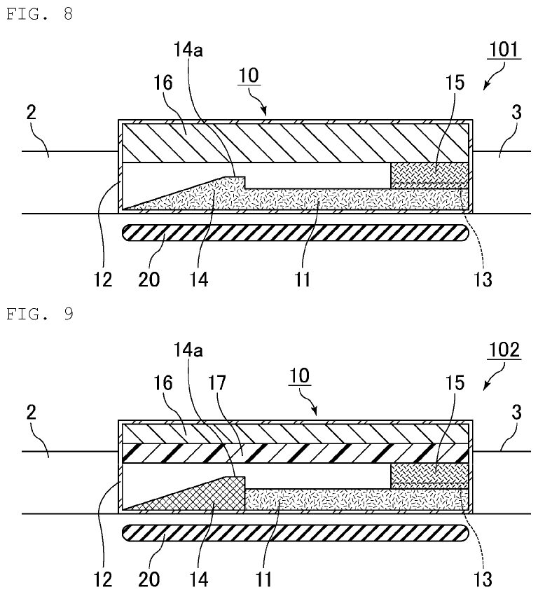

FIG. 7 is a sectional view schematically showing a mist CVD film formation device not including a mist flow restricting member. A mist CVD film formation device 1′ shown in FIG. 7 does not include the mist flow restricting member 15 on the downstream side of the mist flow with respect to the stage 11. Thus, the film forming chamber interior sectional area, which is the sectional area of the space in the film forming chamber, is the same as the outflow port sectional area, which is the sectional area of the space in the mist outflow port. Specifically, the sectional area is the same as the film forming chamber interior sectional area S1 shown in FIG. 5. In this case, evaporation of the liquid constituting the mist easily proceeds because the internal pressure in the film forming chamber is low, and there is a high possibility that the liquid comes into contact with the film forming target in a mist state in which the raw material component precipitates. Thus, it is difficult to obtain a high-quality film.

The mist CVD film formation device 1′ shown in FIG. 7 is not the mist CVD film formation device of the present invention.

In the mist CVD film formation device of the present invention, the thermal conductivity of the member located close to the mist inflow port relative to the stage in the film forming chamber is preferably lower than the thermal conductivity of the material of the stage.

When the thermal conductivity of the member located close to the mist inflow port relative to the stage in the film forming chamber is high, a region on the upstream side of the stage in the film forming chamber tends to have a high temperature due to heating by the heater. Thus, heat received by the film forming mist before the film forming mist reaches the stage increases, so that evaporation of the liquid constituting the mist easily proceeds, and particles precipitate, leading to deterioration of the film quality and deterioration of the film formation rate.

Thus, by reducing the thermal conductivity of the member located close to the mist inflow port relative to the stage in the film forming chamber, it is possible to prevent the temperature of the region on the upstream side of the stage in the film forming chamber from increasing, and to obtain a high-quality film at a high film formation rate.

Examples of the member having such a relationship include a member in which the stage is a metal, and the member located close to the mist inflow port is a ceramic such as a metal oxide, a metal carbide, or a metal nitride, or glass.

Examples of the metal as a material of the stage include stainless steel (SUS), copper, and aluminum. The surface of the metal as the material of the stage may be subjected to a surface treatment by a known method, and it is preferable to prevent the reaction between the material of the stage and the components contained in the film forming mist by the surface treatment.

Examples of the ceramics to be the member located close to the mist inflow port include zircon cordierite, cordierite, alumina, zirconia, mullite, titanium oxide, titanium nitride, silicon nitride, silicon carbide, zinc oxide, forsterite, steatite, sialon, and the like. The glass is not particularly limited, and examples thereof include soda-lime silicate glass, aluminosilicate glass, borosilicate glass, alkali-free glass, and the like.

Among them, a combination in which the material of the stage is stainless steel and the material of the member located close to the mist inflow port is zircon cordierite is preferable.

The material constituting the stage preferably has a high thermal conductivity in order to transfer heat to the film forming target and the value of the thermal conductivity is preferably, for example, 10 W/mK or more.

The thermal conductivity of the member located close to the mist inflow port is preferably, for example, 5 W/mK or less in order to make it difficult for heat to be transferred to the film forming mist.

In the mist CVD film formation device 1 shown in FIGS. 2 and 3, the slope 14 is provided as a member located close to the mist inflow port 12 relative to the stage 11 in the film forming chamber 10.

The thermal conductivity of the material of the slope 14 is preferably lower than the thermal conductivity of the material of the stage 11, and the slope 14 is preferably made of the above ceramic material, more preferably zircon cordierite.

In the mist CVD film formation device 1 shown in FIGS. 2 and 3, a difference between the material of the stage 11 and the material of the slope 14 is indicated by hatching the stage 11 and the slope 14 different from each other.

The slope 14 has a shape in which the mist inflow port 12 side is low and the stage 11 side is high. The film forming mist 6 flowing into the film forming chamber 10 from the mist inflow port 12 flows while ascending along the inclination of the slope 14.

In the fine channel type mist CVD film formation device, the distance between the surface of the film forming target and the top plate is narrower with respect to the size of the mist inflow port in the film forming chamber. By gradually narrowing the flow path through which the film forming mist flows by the slope, the flow of the film forming mist can be prevented from being disturbed.

The slope 14 has the flat surface 14a on the side close to the stage.

The flat surface 14a is preferably a surface coinciding with the surface of the film forming target. It is preferable to adjust the shape of the slope 14 in accordance with the thickness of the film forming target such that the flat surface 14a coincides with the surface of the film forming target.

FIG. 8 is an enlarged sectional view schematically showing an example of a mist CVD film formation device in which the material of the slope is the same as a material of the stage.

In the mist CVD film formation device 101 shown in FIG. 8, the fact that the material of the stage 11 and the material of the slope 14 are the same is shown by hatching the stage 11 and the slope 14 similarly.

A device in which the material of the stage 11 and the material of the slope 14 are the same, is also included in the mist CVD film formation device of the present invention; however, the film forming rate decreases as compared with the case where the thermal conductivity of the material of the slope is low.

In the mist CVD film formation device of the present invention, the thermal conductivity of the member located on the top surface of the film forming chamber is preferably lower than the thermal conductivity of the material of the stage.

In the film forming chamber, the film forming mist flows near the top surface of the film forming chamber before reaching the stage. In particular, when a slope is provided, the film forming mist flows while ascending along the inclination of the slope and collides with the top surface of the film forming chamber. When the temperature of the top surface of the film forming chamber is high, heat received by the film forming mist before the film forming mist reaches the stage increases, evaporation of the liquid constituting the mist is likely to proceed, and precipitation of particles occurs, leading to deterioration of film quality.

Thus, by lowering the thermal conductivity of the member located on the top surface of the film forming chamber, it is possible to prevent the temperature of the top surface of the film forming chamber from increasing and to obtain a high-quality film.

In view of the above mechanism, it is preferable to lower the thermal conductivity of the member located on the top surface of the film forming chamber on the upstream side of the stage (the side closer to the mist inflow port) in the top surface of the film forming chamber. On the downstream side of the stage (the side close to the mist outflow port), the effect does not change if the thermal conductivity of the member located on the top surface of the film forming chamber is not lowered. However, since it takes a lot of time and effort in the production when the material of the top surface is separately produced, the thermal conductivity of the member located on the top surface of the film forming chamber may be lowered on the downstream side of the stage as well as on the upstream side of the stage.

As the member located on the top surface of the film forming chamber and having thermal conductivity lower than the thermal conductivity of the material of the stage, ceramics such as metal oxides, metal carbides, and metal nitrides, or glass, which are mentioned as preferable materials for the member located close to the mist inflow port, can be preferably used. The material of the stage is the same as the material described above. A combination in which the material of the stage is stainless steel, and the material of the member located on the top surface of the film forming chamber is zircon cordierite is preferable.

The thermal conductivity of the member located on the top surface of the film forming chamber is preferably, for example, 5 W/mK or less in order to make it difficult for heat to be transferred to the film forming mist.

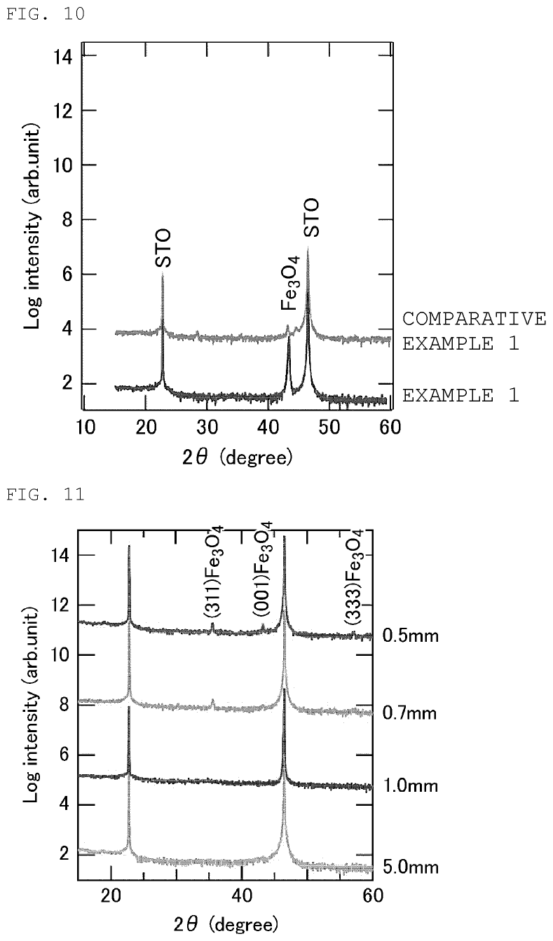

FIG. 9 is an enlarged sectional view schematically showing an example of a mist CVD film formation device including a top plate having low thermal conductivity.

A mist CVD film formation device 102 shown in FIG. 9 includes a top plate 17 having low thermal conductivity as a member constituting the top surface of the film forming chamber 10. The top plate 17 is additionally provided in addition to the top plate 16.

The top plate 17 having low thermal conductivity may be provided, or the original top plate 16 may be made of a material having low thermal conductivity.

Another aspect of a mist CVD film formation device of the present invention includes: a film forming chamber including: a mist inflow port through which a film forming mist containing a mist of a film forming raw material and a carrier gas flows into the film forming chamber, a stage that supports a film forming target, and a mist outflow port through which the film forming mist flows out of the film forming chamber, wherein a thermal conductivity of a first member located close to the mist inflow port relative to the stage in the film forming chamber is lower than a thermal conductivity of a material of the stage; and a heater that heats the stage.

In the mist CVD film formation device, by lowering the thermal conductivity of the member located close to the mist inflow port relative to the stage in the film forming chamber, it is possible to prevent the temperature of the region on the upstream side of the stage in the film forming chamber from increasing, and to obtain a high-quality film at a high film forming rate.

The material preferable as the material of the stage and the member located close to the mist inflow port relative to the stage in the film forming chamber can be the same as the material described above.

In the mist CVD film formation device according to this aspect, the outflow port sectional area may be the same as the film forming chamber interior sectional area, and the outflow port sectional area may be larger than the film forming chamber interior sectional area.

Still another aspect of a mist CVD film formation device of the present invention includes: a film forming chamber including: a mist inflow port through which a film forming mist containing a mist of a film forming raw material and a carrier gas flows into the film forming chamber, a stage that supports a film forming target, and a mist outflow port through which the film forming mist flows out of the film forming chamber, wherein a thermal conductivity of a member located on a top surface of the film forming chamber is lower than a thermal conductivity of a material of the stage; and a heater that heats the stage.

In the mist CVD film formation device, by lowering the thermal conductivity of the member located on the top surface of the film forming chamber, it is possible to prevent the temperature of the top surface of the film forming chamber from increasing and to obtain a high-quality film.

The material preferable as the material of the stage and the member located on the top surface of the film forming chamber can be the same as the material described above.

In the mist CVD film formation device according to this aspect, the outflow port sectional area may be the same as the film forming chamber interior sectional area, and the outflow port sectional area may be larger than the film forming chamber interior sectional area.

In the film formation method of the present invention, a film forming mist containing a mist of a film forming raw material and a carrier gas is caused to flow into a film forming chamber of the mist CVD film formation device of the present invention, and film formation by a mist CVD method is performed on a film forming target placed on a stage.

At the time of film formation, the distance between the surface of the film forming target placed on the stage and the top plate is preferably 10 mm or less. In addition, it is preferable that a slope is provided in the mist CVD film formation device, the slope has a flat surface on the side close to the stage, and the flat surface coincides with the surface of the film forming target.

The film forming mist after film formation is performed on the film forming target is caused to flow out to the outside of the film forming chamber from the mist outflow port.

### EXAMPLES

Hereinafter, experimental results of film formation using the mist CVD film formation device of the present invention are shown.

### Example 1

In Example 1, the mist CVD film formation device of the form shown in FIGS. 2 and 3 was used in the device of the form shown in FIG. 1. SUS was used for the top plate, and zircon cordierite was used for the slope.

The mist CVD film formation device includes a mist flow restricting member. The material of the mist flow restricting member is SUS, and the length (length indicated by double-headed arrow L2 in FIG. 3) of the mist flow restricting member along the flowing direction of the film forming mist is 20 mm.

The rectangle constituting the film forming chamber interior sectional area S1 has a width (W1 in FIG. 5) of 35 mm×a height (T1 in FIG. 5) of 1.7 mm, and the rectangle constituting the outflow port sectional area S2 has a width (W2 in FIG. 6) of 20 mm×a height (T2 in FIG. 6) of 0.5 mm.

A raw material solution for mist CVD was prepared by dissolving iron (III) acetylacetonate (Fe(acac)₃) in a mixed solvent of methanol and water at a concentration of 1 mmol/L. The amount of water is 2.5 wt %. The prepared raw material solution was made into a mist using a mist generator using an ultrasonic transducer of 2.4 MHZ, and conveyed into the film forming chamber by N₂ gas. The N₂ gas flow rate at this time is 3.5 L/min.

The entire film forming chamber of the device shown in FIG. 2 was heated by a mantle heater set at 400° C., and a film was formed on a strontium titanate (STO) substrate for 15 minutes.

### Comparative Example 1

Film formation was performed under the same apparatus and film forming conditions as in Example 1 except that the mist CVD film formation device did not include the mist flow restricting member.

FIG. 10 is a graph showing XRD (X-ray diffraction) patterns of thin films produced in Example 1 and Comparative Example 1.

As shown in FIG. 10, it can be seen that Fe₃O₄ is epitaxially grown on the STO substrate in Example 1 in which the outflow port sectional area is reduced using the mist flow restricting member. On the other hand, in Comparative Example 1 in which the mist flow restricting member is not used, only a very small peak of Fe₃O₄ can be confirmed.

In addition, the film thickness of the film formed in Example 1 was about 1147 nm, and the film thickness of the film formed in Comparative Example 1 was about 943 nm. Although the film thickness is thinner in Comparative Example 1, since a sufficiently thick film is formed, it is considered that the reason why only a small peak of Fe₃O₄ is confirmed in Comparative Example 1 in the XRD pattern shown in FIG. 10 is that the film quality of the film formed in Comparative Example 1 is poor.

From this result, it can be seen that a high-quality film can be produced by making the outflow port sectional area smaller than the film forming chamber interior sectional area.

### Comparative Example 2

FIG. 11 is a graph showing the XRD pattern of a thin film prepared by changing the height of the space in the film forming chamber within a range of 0.5 mm, 0.7 mm, 1.0 mm, and 5.0 mm when the mist flow restricting member is not used.

From FIG. 11, it can be seen that although the peak of Fe₃O₄ can be confirmed as the height of the space in the film forming chamber decreases, unlike the case of Example 1 in FIG. 10, all the peaks are of the polycrystalline film. From this, it can be seen that although the film quality is improved by reducing the height of the space in the film forming chamber, a high-quality film cannot be produced only by this.

### Example 2

A Fe₃O₄ film was compared when a film was formed using zircon cordierite (thermal conductivity: 1.3 W/mK) or aluminum (thermal conductivity: 138 W/mK) as a slope member. Film formation was performed under the same conditions as in Example 1 except for the material of the slope. As a result, it was found that although the film thickness was about 1147 nm in the case of using zircon cordierite as the slope member (Example 1), the film thickness was about 620 nm in the case of using aluminum as the slope member, and the film thickness was about half of that in the case of zircon cordierite. In both cases, it was found from the XRD pattern that the Fe₃O₄ film was epitaxially grown on the STO substrate.

By using zircon cordierite as the slope member, deposition of particles until the mist has reached the stage can be suppressed, and the film formation rate was improved.

The thermal conductivity of SUS as the material of the stage is usually 30 W/mK or less.

### Example 3

A Fe₃O₄ film formed using SUS or zircon cordierite as a member located on the top surface of the film forming chamber was compared. Film formation was performed under the same conditions as in Example 1 except for the material of the top plate. As a result, it was found that a room temperature resistivity of the film was about 72.3 mΩcm when SUS was used for the top plate (Example 1), whereas the room temperature resistivity was as low as about 37.8 mΩcm when zircon cordierite was used for the top plate.

When the number of grain boundaries of crystals in the film is small, grain boundary resistance decreases, and therefore when the resistance is small, it can be determined that the film is a high-quality film. From this, it has been found that a high-quality film can be produced by using a member having low thermal conductivity as the member located on the top surface of the film forming chamber.

The internal pressure of the film forming chamber can also be increased by providing a mechanism for regulating gas discharge in the mist discharge pipe. For example, a method of narrowing the mist discharge pipe, disposing a flow valve for regulating a gas discharge amount in the mist discharge pipe, or disposing a baffle plate in the mist discharge pipe can be cited. These methods can also be used in combination with the mist CVD film formation device of the present invention.

### DESCRIPTION OF REFERENCE SYMBOLS

1, 1′, 101, 102: Mist CVD film formation device
2: Mist introduction pipe
3: Mist discharge pipe
4: Gas supply unit
5: Mist generator
6: Film forming mist
6a: Liquid
6b: Raw material component
6c: Nanoparticle
6d: Large particle
10: Film forming chamber
11: Stage
12: Mist inflow port
13: Mist outflow port
14: Slope
14a: Flat surface
15: Mist flow restricting member
16: Top plate
17: Top plate having low thermal conductivity
20: Heater
30: Film forming target
S1: Film forming chamber interior sectional area
S2: Outflow port sectional area

1. A mist CVD film formation device comprising:
a film forming chamber including:
a mist inflow port through which a film forming mist containing a mist of a film forming raw material and a carrier gas flows into the film forming chamber,
a stage that supports a film forming target, and
a mist outflow port through which the film forming mist flows out of the film forming chamber,
wherein an outflow port sectional area is smaller than a film forming chamber interior sectional area, the film forming chamber interior sectional area is a sectional area of a space in the film forming chamber in a cut surface obtained by cutting in a section orthogonal to a flowing direction of the film forming mist on the stage, and the outflow port sectional area is a sectional area of a space of the mist outflow port in a cut surface obtained by cutting the mist outflow port in the section orthogonal to the flowing direction of the film forming mist; and
a heater that heats the stage.

2. The mist CVD film formation device according to claim 1, wherein a height of the space in the film forming chamber on the stage is 10 mm or less.

3. The mist CVD film formation device according to claim 1, wherein a thermal conductivity of a first member located close to the mist inflow port relative to the stage in the film forming chamber is lower than a thermal conductivity of a material of the stage.

4. The mist CVD film formation device according to claim 3, wherein a thermal conductivity of a second member located on a top surface of the film forming chamber is lower than the thermal conductivity of the material of the stage.

5. The mist CVD film formation device according to claim 1, wherein a thermal conductivity of a member located on a top surface of the film forming chamber is lower than a thermal conductivity of a material of the stage.

6. The mist CVD film formation device according to claim 1, wherein the film forming chamber includes a slope that has a low side at the mist inflow port and a high side at the stage and is positioned on close to the mist inflow port relative to the stage in the film forming chamber.

7. The mist CVD film formation device according to claim 6, wherein the slope has a flat surface on a side thereof close to the stage.

8. The mist CVD film formation device according to claim 1, wherein a height of a space of the mist outflow port is smaller than the height of the space in the film forming chamber on the stage.

9. The mist CVD film formation device according to claim 1, wherein a width of the space of the mist outflow port is smaller than a width of the space in the film forming chamber on the stage.

10. A mist CVD film formation device comprising:
a film forming chamber including:
a mist inflow port through which a film forming mist containing a mist of a film forming raw material and a carrier gas flows into the film forming chamber,
a stage that supports a film forming target, and
a mist outflow port through which the film forming mist flows out of the film forming chamber,
wherein a thermal conductivity of a first member located close to the mist inflow port relative to the stage in the film forming chamber is lower than a thermal conductivity of a material of the stage; and
a heater that heats the stage.

11. The mist CVD film formation device according to claim 10, wherein a height of the space in the film forming chamber on the stage is 10 mm or less.

12. The mist CVD film formation device according to claim 10, wherein a thermal conductivity of a second member located on a top surface of the film forming chamber is lower than the thermal conductivity of the material of the stage.

13. The mist CVD film formation device according to claim 10, wherein the film forming chamber includes a slope that has a low side at the mist inflow port and a high side at the stage and is positioned on close to the mist inflow port relative to the stage in the film forming chamber.

14. The mist CVD film formation device according to claim 13, wherein the slope has a flat surface on a side thereof close to the stage.

15. The mist CVD film formation device according to claim 10, wherein a height of a space of the mist outflow port is smaller than the height of the space in the film forming chamber on the stage.

16. The mist CVD film formation device according to claim 10, wherein a width of the space of the mist outflow port is smaller than a width of the space in the film forming chamber on the stage.

17. A mist CVD film formation device comprising:
a film forming chamber including:
a mist inflow port which is an opening through which a film forming mist containing a mist of a film forming raw material and a carrier gas flows in,
a stage on which a film forming target is placed, and
a mist outflow port which is an opening through which the film forming mist flows out,
wherein a thermal conductivity of a member located on a top surface of the film forming chamber is lower than a thermal conductivity of a material of the stage; and
a heater that heats the stage.

18. A film formation method, the method comprising:
causing a film forming mist containing a mist of a film forming raw material and a carrier gas to flow into the film forming chamber of the mist CVD film formation device according to claim 1; and
forming a film by a mist CVD method on a film forming target placed on the stage.

19. A film formation method, the method comprising:
causing a film forming mist containing a mist of a film forming raw material and a carrier gas to flow into the film forming chamber of the mist CVD film formation device according to claim 10; and
forming a film by a mist CVD method on a film forming target placed on the stage.

20. A film formation method, the method comprising:
causing a film forming mist containing a mist of a film forming raw material and a carrier gas to flow into the film forming chamber of the mist CVD film formation device according to claim 13; and
forming a film by a mist CVD method on a film forming target placed on the stage.
